(19) United States
(12) Patent Application Publication
(10) Pub. No.: US 2024/0266622 A1
(43) Pub. Date: Aug. 8, 2024

(54) MINUTE SHORT CIRCUIT DETECTION DEVICE, MINUTE SHORT CIRCUIT DETECTION METHOD, STORAGE MEDIUM, AND BATTERY UNIT

(71) Applicant: HONDA MOTOR CO., LTD., Tokyo (JP)

(72) Inventors: Takuya Taniuchi, Wako-shi (JP); Toshimitsu Tanaka, Wako-shi (JP); Makiko Takahashi, Wako-shi (JP); Ryo Shimizu, Wako-shi (JP); Kizashi Iwakiri, Wako-shi (JP)

(21) Appl. No.: 18/420,808

(22) Filed: Jan. 24, 2024

(30) Foreign Application Priority Data
Feb. 2, 2023 (JP) 2023-014699

(51) Int. Cl. H01M 10/48; H01M 10/0562; H01M 10/0585

(52) U.S. Cl. CPC H01M 10/48; H01M 10/0562; H01M 10/0585

(57) ABSTRACT

A minute short circuit detection device that detects whether a minute short circuit has occurred in a battery unit including a positive electrode layer, an electrolyte layer, and a negative electrode layer includes: a voltage detecting unit configured to detect a voltage of the battery unit; a current detecting unit configured to detect a current flowing in the battery unit; a storage device configured to store a program; and a hardware processor. The hardware processor is configured to execute the program stored in the storage device to determine whether a minute short circuit has occurred in the battery unit on the basis of a detection result of the voltage or the current. The hardware processor determines whether the minute short circuit has occurred on the basis of the detection result of the current and a sign of a voltage applied to the battery unit in a dormant state.

### CROSS-REFERENCE TO RELATED APPLICATION

Priority is claimed on Japanese Patent Application No. 2023-014699, filed Feb. 2, 2023, the content of which is incorporated herein by reference.

### BACKGROUND

### Field of the Invention

The present invention relates to a minute short circuit detection device, a minute short circuit detection method, a storage medium, and a battery unit.

### Description of Related Art

Recently, secondary batteries contributing to enhancement in energy efficiency have been studied and developed in order to secure access to sustainable and advanced energy which can be reasonably trusted by more people. For example, a technique of detecting a defect of a single battery from a change in internal resistance at the time of charging in a battery block including a plurality of single batteries has been proposed (Japanese Unexamined Patent Application, First Publication No. 2003-204627). For example, a technique of determining whether a short circuit has occurred in a power storage unit on the basis of detection results of a voltage across both terminals of the power storage unit and a current flowing in the power storage unit at the time of charging has also been proposed (PCT International Publication No. WO2017/217092).

### SUMMARY

However, in the related art, a minute short circuit of a battery may not be able to be accurately detected due to restrictions of measuring means provided in the battery.

The present invention was made in consideration of the aforementioned circumstances and an objective thereof is to provide a minute short circuit detection device, a minute short circuit detection method, a storage medium, and a battery unit that can more accurately detect a minute short circuit of a battery. Another objective is to contribute to enhancement in efficiency of energy.

A minute short circuit detection device, a minute short circuit detection method, a storage medium, and a battery unit according to the present invention employ the following configurations.

(1) A minute short circuit detection device according to an aspect of the present invention is a minute short circuit detection device that detects whether a minute short circuit has occurred in a battery unit including a positive electrode layer, an electrolyte layer, and a negative electrode layer, the minute short circuit detection device including: a voltage detecting unit configured to detect a voltage of the battery unit; a current detecting unit configured to detect a current flowing in the battery unit; a storage device configured to store a program; and a hardware processor, wherein the hardware processor is configured to execute the program stored in the storage device to determine whether a minute short circuit has occurred in the battery unit on the basis of a detection result of the voltage or the current, and wherein the hardware processor determines whether a minute short circuit has occurred on the basis of the detection result of the current and a sign of a voltage applied to the battery unit in a dormant state.

(2) In the aspect of (1), the battery unit may include a first negative-electrode current collector, a first negative-electrode active material layer, a first electrolyte layer, a first positive-electrode active material layer, a positive-electrode current collector, a second positive-electrode active material layer, a second electrolyte layer, a second negative-electrode active material layer, and a second negative-electrode current collector, and the current detecting unit may be provided in at least the first negative-electrode current collector and the second negative-electrode current collector.

(3) In the aspect of (2), the current detecting unit may be additionally provided in the positive-electrode current collector.

(4) In the aspect of (1), the battery unit may include a first positive-electrode current collector, a first positive-electrode active material layer, a first electrolyte layer, a first negative-electrode active material layer, a negative-electrode current collector, a second negative-electrode active material layer, a second electrolyte layer, a second positive-electrode active material layer, and a second positive-electrode current collector, and the current detecting unit may be provided in at least the first positive-electrode current collector and the second positive-electrode current collector.

(5) In the aspect of (4), the current detecting unit may be additionally provided in the negative-electrode current collector.

(6) In the aspect of (1), an electrolyte constituting the electrolyte layer may be a solid electrolyte.

(7) In the aspect of (1), the battery unit may include one or more basic units in which two batteries are connected in parallel, and the hardware processor may determine whether a current in each basic unit flows back on the basis of the sign of a voltage applied to the basic unit.

(8) In the aspect of (1), the battery unit may include a plurality of basic units in which two batteries are connected in parallel, and the hardware processor may detect a basic unit into which a current continues to flow out of the plurality of basic units on the basis of the sign of a voltage applied to each basic unit.

(9) In the aspect of (1), the hardware processor may determine whether a self-discharge rate of the battery unit is greater than a prescribed value on the basis of a voltage applied to the battery unit.

(10) In the aspect of (1), the hardware processor may perform a motion of curbing charging of the battery unit when it is determined that a minute short circuit has occurred in the battery unit.

(11) A minute short circuit detection method according to another aspect of the present invention is a minute short circuit detection method that is performed by a minute short circuit detection device that detects whether a minute short circuit has occurred in a battery unit including a positive electrode layer, an electrolyte layer, and a negative electrode layer, the minute short circuit detection method causing the minute short circuit detection device to perform: detecting a voltage of the battery unit; detecting a current flowing in the battery unit; and determining whether a minute short circuit has occurred in the battery unit on the basis of a detection result of the voltage or the current, wherein the minute short circuit detection device determines whether the minute short circuit has occurred on the basis of the detection result of the current and the sign of a voltage applied to the battery unit in a dormant state.

(12) A storage medium according to another aspect of the present invention is a non-transitory computer-readable storage medium storing a program that is executed by a minute short circuit detection device that detects whether a minute short circuit has occurred in a battery unit including a positive electrode layer, an electrolyte layer, and a negative electrode layer, the program causing the minute short circuit detection device to perform: detecting a voltage of the battery unit; detecting a current flowing in the battery unit; and determining whether a minute short circuit has occurred in the battery unit on the basis of a detection result of the voltage or the current, wherein the minute short circuit detection device determines whether the minute short circuit has occurred on the basis of the detection result of the current and the sign of a voltage applied to the battery unit in a dormant state.

(13) A battery unit according to another aspect of the present invention is a battery unit in which a first negative-electrode current collector, a first negative-electrode active material layer, a first electrolyte layer, a first positive-electrode active material layer, a positive-electrode current collector, a second positive-electrode active material layer, a second electrolyte layer, a second negative-electrode active material layer, and a second negative-electrode current collector are sequentially stacked, wherein a current detecting unit is provided in at least the first negative-electrode current collector and the second negative-electrode current collector.

(14) A battery unit according to another aspect of the present invention is a battery unit in which a first positive-electrode current collector, a first positive-electrode active material layer, a first electrolyte layer, a first negative-electrode active material layer, a negative-electrode current collector, a second negative-electrode active material layer, a second electrolyte layer, a second positive-electrode active material layer, and a second positive-electrode current collector are sequentially stacked, and wherein a current detecting unit is provided in at least the first positive-electrode current collector and the second positive-electrode current collector.

According to the aspects of (1) to (14), it is possible to provide a minute short circuit detection device, a minute short circuit detection method, a storage medium, and a battery unit that can more accurately detect a minute short circuit of a battery.

### BRIEF DESCRIPTION OF THE DRAWINGS

FIG. 1 is a diagram illustrating an example of a configuration of an all-solid-state battery unit (a basic unit) according to an embodiment.

FIG. 2 is a diagram illustrating an example of a configuration of an all-solid-state battery unit according to the embodiment.

FIG. 3 is a diagram illustrating an example of a configuration of a minute short circuit detection device according to the embodiment.

FIG. 4 is a flowchart illustrating an example of a process flow in which the minute short circuit detection device determines whether an abnormality has occurred in a target all-solid-state battery unit.

FIG. 5 is a diagram illustrating an example of an all-solid-state battery unit including a flow-in sustaining unit.

FIG. 6 is a timing chart illustrating an example of determination results of second determination.

FIG. 7 is a timing chart illustrating an example of determination results of first determination.

FIG. 8 is a diagram illustrating an example of a configuration of a stack type all-solid-state battery unit according to the related art.

### DESCRIPTION OF EMBODIMENTS

Hereinafter, a minute short circuit detection device, a minute short circuit detection method, a storage medium and a battery unit according to an embodiment of the present invention will be described with reference to the accompanying drawings.

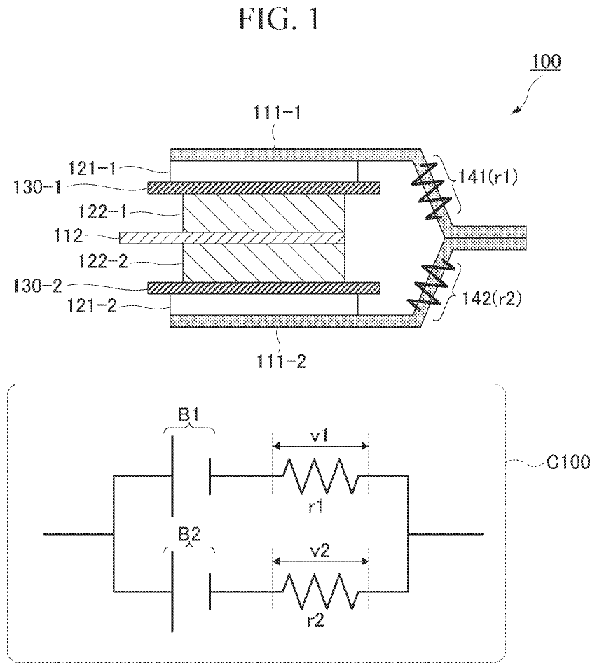

FIG. 1 is a diagram illustrating an example of a configuration of an all-solid-state battery unit 100 according to an embodiment. The all-solid-state battery unit 100 includes negative-electrode current collectors 111-1 and 111-2, a positive-electrode current collector 112, negative-electrode laminates 121-1 and 121-2 which are negative-electrode active material layers, positive-electrode laminates 122-1 and 122-2 which are positive-electrode active material layers, solid electrolyte layers 130-1 and 130-2, and current direction sensing elements 141 and 142. The all-solid-state battery unit 100 has a configuration in which two all-solid-state batteries 101 and 102 are stacked to share the positive-electrode current collector 112. Electrical characteristics of the all-solid-state battery unit 100 with this configuration are the same as illustrated in a circuit diagram C100. The circuit diagram C100 has a configuration which includes batteries B1 and B2 corresponding to the two all-solid-state batteries 101 and 102 and resistors r1 and r2 corresponding to the two current direction sensing elements 141 and 142 and in which positive electrodes of the batteries B1 and B2 are connected and negative electrodes thereof are connected to each other via the resistors r1 and r2.

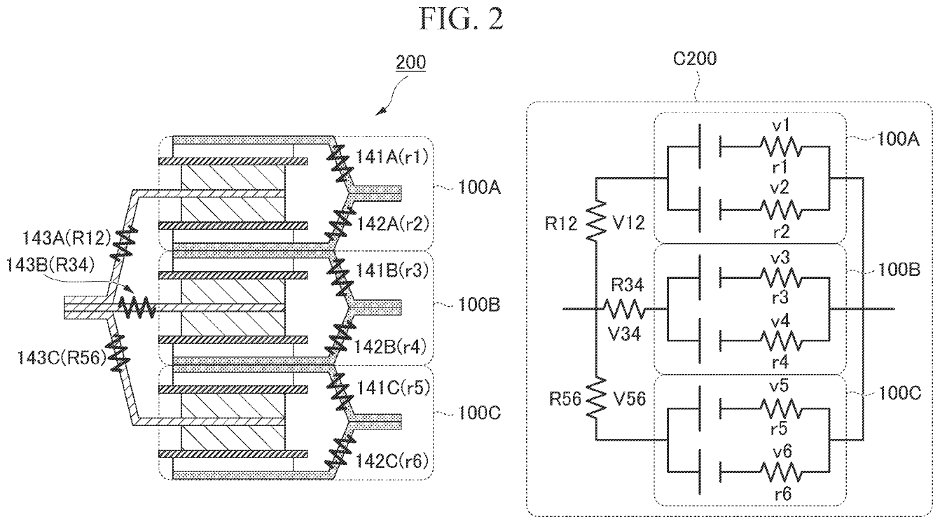

FIG. 2 is a diagram illustrating an example of a configuration of an all-solid-state battery unit 200 according to the embodiment. The all-solid-state battery unit 200 has a configuration in which three all-solid-state battery units 100A, 100B, and 100C with the all-solid-state battery unit 100 illustrated in FIG. 1 as a unit configuration are connected in parallel. Electrical characteristics of the all-solid-state battery unit 200 with this configuration are the same as illustrated in a circuit diagram C200. Symbols A to C added to reference signs in the drawing are for distinguishing the corresponding all-solid-state battery units 100. In the following description, an all-solid-state battery unit 100 in the all-solid-state battery unit 200 may be referred to as a basic unit 100.

The all-solid-state battery unit 200 includes a current direction sensing element 143 on an input side of each all-solid-state battery unit 100 in addition to the current direction sensing elements 141 and 142 of the all-solid-state battery unit 100. Specifically, a current direction sensing element 143A is provided on the input side of the all-solid-state battery unit 100A, a current direction sensing element 143B is provided on the input side of the all-solid-state battery unit 100B, and a current direction sensing element 143C is provided on the input side of the all-solid-state battery unit 100C. The current direction sensing elements 141, 142, and 143 may be so-called shunt resistors which are resistors for detecting a current of a circuit.

Examples of the configurations of the all-solid-state battery units 100 and 200 have been described above with reference to FIGS. 1 and 2, and the configurations of the all-solid-state battery units 100 and 200 may be arbitrarily modified as long as a minute short circuit detection method which will be described below can be applied. For example, addition of a layer between a negative electrode and an electrolyte layer is conceivable as a modified example. FIG. 1 illustrates an example in which the all-solid-state battery unit 100 includes the current direction sensing elements r1 and r2, but the current direction sensing elements r1 and r2 may be provided outside of the all-solid-state battery unit 100 as long as the current direction sensing elements r1 and r2 are electrically connected to a measurement target part and a current direction in the part can be detected. For example, the current direction sensing elements r1 and r2 may be provided outside of an armor member (for example, a laminated film) in which various stacked members constituting the all-solid-state battery unit 100 are accommodated.

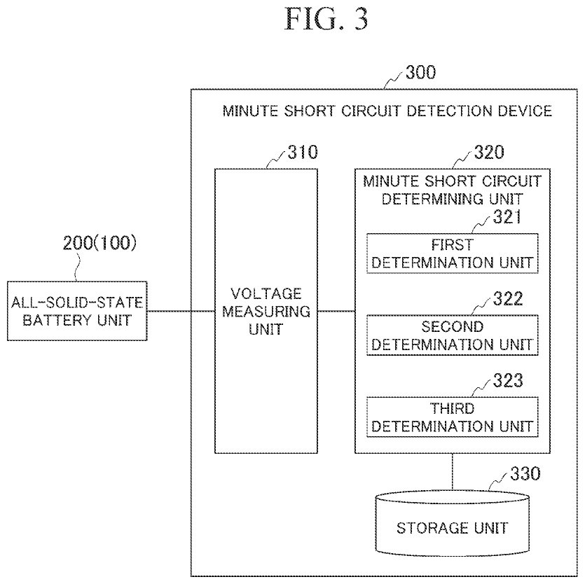

FIG. 3 is a diagram illustrating an example of a configuration of a minute short circuit detection device 300 according to the embodiment. The minute short circuit detection device 300 includes, for example, a voltage measuring unit 310, a minute short circuit determining unit 320, and a storage unit 330. Some or all of such functional units are realized, for example, by causing a hardware processor such as a central processing unit (CPU) to execute a program (software). Some or all of the functional units of the minute short circuit detection device 300 may be realized by hardware (a circuit part including circuitry) such as a large-scale integration (LSI), an application-specific integrated circuit (ASIC), a field-programmable gate array (FPGA), or a graphics processing unit (GPU) or may be cooperatively realized by software and hardware. The program may be stored in a storage device (a storage device including a non-transitory storage medium) such as a storage unit 170 in advance or may be stored in a detachable storage medium such as a DVD or CD-ROM and installed in the storage unit 330 or the like of the minute short circuit detection device 300 by setting the storage medium (a non-transitory storage medium) to a drive device.

The voltage measuring unit 310 measures an output voltage of an all-solid-state battery unit connected to the minute short circuit detection device 300. For example, the voltage measuring unit 310 has a tester function of detecting a voltage and a contactor function of blocking a current and can control charging/discharging states of an all-solid-state battery unit which is a measurement target and measure an output voltage of the all-solid-state battery unit in a dormant state (hereinafter referred to as a “dormant voltage”). The dormant state is a state in which a cell voltage continues to change due to self-discharge after charging/discharging of an all-solid-state battery unit has stopped. The cell voltage of an all-solid-state battery unit does not ideally change after charging/discharging has stopped, but the cell voltage may actually change in a dormant state due to a voltage drop of an over-voltage or slight self-discharge. The all-solid-state battery unit changes to a non-discharge state via the dormant state after charging/discharging has been performed. The voltage measuring unit 310 outputs a measurement result to the minute short circuit determining unit 320. An all-solid-state battery unit which is connected to the voltage measuring unit 310 may be one of the all-solid-state battery units 100 and 200. It is assumed that the voltage measuring unit 310 can detect a voltage applied to the current direction sensing elements 141 and 142 of the all-solid-state battery unit 100 or 200 as a dormant voltage of the all-solid-state battery unit 100 or 200. The voltage measuring unit 310 can also calculate the magnitude of the current flowing in the current direction sensing elements 141 and 142 on the basis of the measurement result of the voltage and resistance values. In the following description, the direction of a current may be replaced with a voltage drop direction, and the sign of a current may be replaced with the sign of a voltage.

The minute short circuit determining unit 320 determines whether a minute short circuit has occurred in the corresponding all-solid-state battery unit on the basis of the dormant voltage of the all-solid-state battery unit measured by the voltage measuring unit 310. The minute short circuit determining unit 320 includes, for example, a first determination unit 321, a second determination unit 322, and a third determination unit 323 and determines whether a minute short circuit has occurred on the basis of the determination results from the first determination unit 321, the second determination unit 322, and the third determination unit 323.

The first determination unit 321 performs determination of a self-discharge rate in an all-solid-state battery unit which is a determination target. The second determination unit 322 determines whether a part into which a current continues to flow (hereinafter referred to as a “flow-in sustaining part”) is included in an all-solid-state battery unit which is a determination target. The third determination unit 323 determines whether a current flows back in an all-solid-state battery unit which is a determination target.

The storage unit 330 is a storage device such as a hard disk drive (HDD), a solid-state drive (SSD), or a flash memory. The storage unit 330 is used as a storage area of a program which is executed by the minute short circuit detection device 300, setting information, or various types of information required for determination of a minute short circuit.

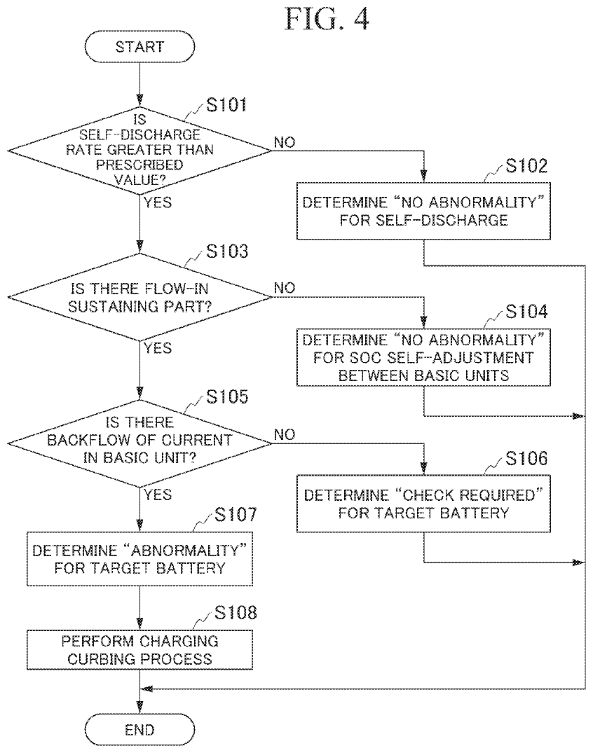

FIG. 4 is a flowchart illustrating an example of a process flow in which the minute short circuit detection device 300 determines whether an abnormality (which includes a minute short circuit) has occurred in a target all-solid-state battery unit. At the time of start of the flowchart, it is assumed that an all-solid-state battery unit which is a determination target (hereinafter referred to as a “target unit”) is connected to the minute short circuit detection device 300, and the voltage measuring unit 310 continuously measures a dormant voltage of the target unit and frequently outputs the measurement result to the minute short circuit determining unit 320.

First, the minute short circuit determining unit 320 determines whether a self-discharge rate of the target unit is greater than a prescribed value using the first determination unit 321 (S101). For example, the minute short circuit determining unit 320 determines whether a voltage of the target unit at the start time of the dormant state is greater than a prescribed value. Here, it is assumed that the prescribed value is stored in the storage unit 330 in advance. The prescribed value may be a value varying according to the type, the configuration, or the like of the target unit. When the self-discharge rate of the target unit is equal to or less than the prescribed value, the minute short circuit determining unit 320 determines that the self-discharge of the target unit is in a normal range and determines that that “no abnormality” occurs in self-discharge in the target unit as a whole (S102).

On the other hand, when the self-discharge rate of the target unit is greater than the prescribed value, the minute short circuit determining unit 320 determines whether there is a flow-in sustaining part in the target unit using the second determination unit 322 (S103). For example, the second determination unit 322 can determine whether there is a flow-in sustaining part by observing current flows in constituent parts in a predetermined period using the current direction sensing elements 143. The minute short circuit detection device 300 can sense a current direction and change of the current direction by measuring a current value with a certain direction defined as positive and with the reverse direction thereof defined as negative and observing change of the sign.

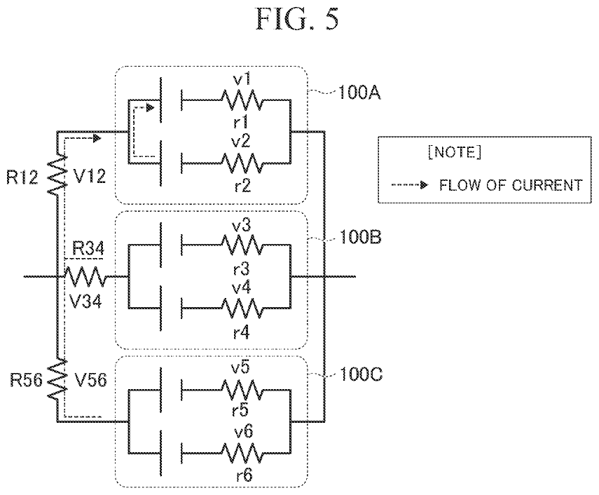

For example, in the circuit diagram C200 of FIG. 2, the all-solid-state battery unit 100 corresponding to the current direction sensing element 143 in which the sign of the current is kept positive in the predetermined period as a result of measurement of currents flowing in the current direction sensing elements 143 with a direction toward a positive electrode of each all-solid-state battery unit 100 (a direction from left to right in the drawing) defined as positive and with the reverse direction thereof (a direction from right to left in the drawing) defined as negative can be identified as a flow-in sustaining part. For example, in the example illustrated in FIG. 5, the current direction sensing element 143A in which the current sign is positive out of the current direction sensing elements 143A, 143B, and 143C can be determined as a flow-in sustaining part.

Description will be continued with reference to FIG. 4. When a flow-in sustaining part is not detected in S103, the minute short circuit determining unit 320 determines that the self-discharge of the target unit is based on normal self-adjustment of a state of charge (SOC) in the all-solid-state battery units 100 and determines that “no abnormality” occurs in self-adjustment of the SOC in the basic units of the target unit (S104). When a flow-in sustaining part is detected in S103, the minute short circuit determining unit 320 determines whether a backflow of a current occurs in the target unit using the third determination unit 323 (S105).

For example, the third determination unit 323 can determine whether a backflow of a current occurs in each all-solid-state battery unit 100 by observing whether the current directions in the current direction sensing element 141 and the current direction sensing element 142 of the all-solid-state battery unit 100 match. For example, the example illustrated in FIG. 5 represents a situation in which the SOC of the all-solid-state battery unit 100A out of the all-solid-state battery units 100A, 100B, and 100C is lower than those of the other units and the all-solid-state battery units 100B and 100C are charged (discharged) to complement differences in SOC from the all-solid-state battery unit 100A (self-adjustment of the SOC) such that an open-circuit voltage (OCV) is stabilized. That is, this is a situation in which a backflow of a current occurs in the all-solid-state battery unit 100A. In this case, for example, the third determination unit 323 can detect that a backflow of a current occurs in the all-solid-state battery unit 100A because a mismatch between the direction (sign) of the current flowing in the current direction sensing element 141A and the direction (sign) of the current flowing in the current direction sensing element 141B is maintained in a predetermined period. In the example illustrated in FIG. 5, when a current flows in the all-solid-state battery unit 100A (that is, the all-solid-state battery unit 100A is a flow-in sustaining part) and the voltage of the all-solid-state battery unit 100A does not increase, the third determination unit 323 may determine that a backflow of a current occurs in the all-solid-state battery unit 100A.

The description will be continued with reference to FIG. 4. When a backflow of a current in the target unit is not detected in S105, the minute short circuit determining unit 320 determines that check is necessary for self-discharge of the target unit (S106). In this case, the minute short circuit determining unit 320 may perform an operation of notifying the minute short circuit detection device 300 that check of the target unit is necessary. For this notification operation, the minute short circuit detection device 300 may include a notification unit such as a display device, an indicator, or a speaker. The notification operation may be notification to an external device by communication. In this case, the minute short circuit detection device 300 may include a communication unit (a communication interface) having a communication function with an external device.

On the other hand, in S105, when a backflow of a current in the target unit is detected, the minute short circuit determining unit 320 determines that a minute short circuit has occurred in the target unit and determines that an “abnormality” has occurred in the target unit (S107). In this case, the minute short circuit determining unit 320 may perform an operation of notifying the minute short circuit detection device 300 that an abnormality has occurred in the target unit. Subsequently, when it is determined in S107 that an abnormality has occurred, the minute short circuit determining unit 320 performs a process of curbing charging (which includes regeneration) of the target unit (a charging curbing process) (S108). For example, when the target unit includes a storage unit that stores information on usage of the target unit, the minute short circuit determining unit 320 may record information indicating that charging of the target unit is not possible in the storage unit as the charging curbing process. For example, the minute short circuit determining unit 320 may be configured to notify a functional unit or an external device using or controlling the target unit that charging of the target unit is not possible as the charging curbing process.

As described above, the process that is performed by the minute short circuit detection device 300 can be roughly divided into a determination process (hereinafter referred to as “first determination”) for identifying an all-solid-state battery unit 100 serving as a flow-in sustaining part in the all-solid-state battery unit 200 in which a plurality of all-solid-state battery units 100 are stacked and a determination process (hereinafter referred to as “second determination”) for detecting whether a backflow of a current in the all-solid-state battery unit 100 occurs. For example, in the example illustrated in FIGS. 4, S101 and S103 correspond to the first determination, and S105 corresponds to the second determination. FIG. 5 illustrates an example in which a backflow of a current has occurred in the all-solid-state battery unit 100A, and determination of whether a backflow of a current has occurred may be performed on the all-solid-state battery units 100A to 100C in S105. FIG. 4 illustrates a minute short circuit detecting process in the all-solid-state battery unit 200 in which the all-solid-state battery units 100 are stacked, and the processes of S103 and S104 may be skipped when a minute short circuit in an all-solid-state battery unit 100 which is a basic unit is detected.

In this way, the minute short circuit detection device 300 can detect a minute short circuit in an all-solid-state battery unit 200 by performing the first determination and the second determination. In this embodiment, the all-solid-state battery unit 200 in which three all-solid-state battery units 100 are stacked is described as an example, but the number of all-solid-state battery units 100 which are stacked may be two or may be four or more. The minute short circuit detection device 300 may determine whether a minute short circuit has occurred using the result of only the second determination when an all-solid-state battery unit 100 is connected thereto as a target unit.

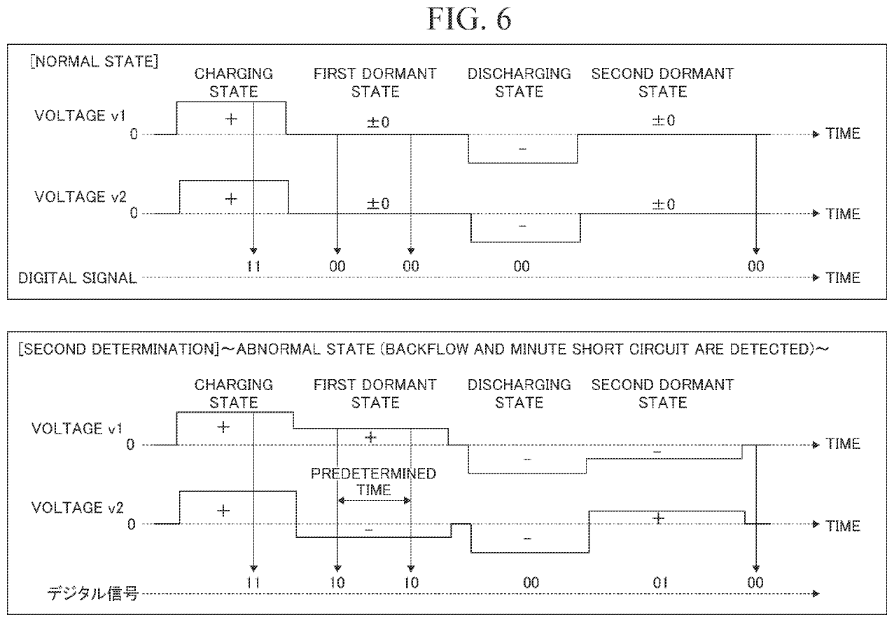

FIG. 6 is a timing chart illustrating an example of determination results of second determination. The upper chart illustrates an example of determination in a normal state, and the lower chart illustrates an example of determination in an abnormal state. The voltage v1 in the drawing corresponds to v1 in FIG. 5 and indicates a voltage applied to the current direction sensing element 141A of the all-solid-state battery unit 100A. Similarly, the voltage v2 in the drawing corresponds to v2 in FIG. 5 and indicates a voltage applied to the current direction sensing element 142A of the all-solid-state battery unit 100A. FIG. 6 illustrates a transition example of a voltage value when the target unit transitions sequentially from a state in which the voltage is 0 to a charging state, a first dormant state after charging has stopped, a discharging state, and a second dormant state after discharging has stopped.

In this case, when the target unit is normal, the same transition will appear both the voltage v1 and the voltage v2. For example, in the example in the normal state in FIG. 6, the voltages in the charging state are positive, and the voltages in the first dormant state, the discharging state, and the second dormant state are equal to or lower than 0. That is, when the signs of the voltages are represented as digital signals (where a positive value is defined as 1 and zero or a negative value is defined as 0), the third determination unit 323 can recognize the state of the all-solid-state battery unit 100A in signal patterns of 11, 00, 00, and 00.

On the other hand, when a backflow of a current has occurred in the target unit (that is, when a minute short circuit has occurred), the voltage v1 and the voltage v2 do not show the same transition patterns. For example, as in the example illustrated in FIG. 6, the voltage values of the current direction sensing element in the charging and discharge states may differ due to electrode-plate resistance but the signs are the same, but the signs in the dormant states may be different. When the signs of the voltages in this example are represented as digital signals, the third determination unit 323 recognizes the states of the all-solid-state battery unit 100A in signal patterns of 11, 10, 00, and 01. For example, in this case, the third determination unit 323 can detect the signal patterns 10 and 01 other than 11 and 00 as an abnormality. The third determination unit 323 does not need to always monitor signal values for detecting an abnormality and can detect whether a backflow of a current has occurred by determining voltage signs at a predetermined timing.

The third determination unit 323 may determine whether a backflow of a current has occurred by combining a plurality of observed signal patterns. For example, the third determination unit 323 may be configured to determine whether a backflow of a current has occurred by recognizing the states when a predetermined operation is performed on a target unit by combination of signal patterns and comparing the observed signal patterns in the target unit with the signal patterns in the normal state. For example, when the observed signal patterns do not match the signal patterns in the normal state, the third determination unit 323 may determine that a backflow of a current has occurred. For example, when the observed signal patterns match the signal patterns in the abnormal state to be detected, the third determination unit 323 may determine that a backflow of a current has occurred. In this case, it is assumed that the signal patterns in the normal state and the signal patterns in the abnormal state to be detected are stored in the storage unit 330 in advance.

As described above with reference to FIG. 4, the third determination unit 323 determines that a backflow of a current has occurred when the signs of the voltages (currents) applied to the current direction sensing elements 141 and 142 in the dormant state do not change in a predetermined period. FIG. 6 illustrates an example in which the third determination unit 323 determines that a backflow of a current has occurred because the signs in the first dormant state do not change in a predetermined period. The signs at two time points are used to determine whether the signs change herein, but the signs at three or more time points may be used to determine whether the signs change. In this case, the third determination unit 323 can also determine whether a backflow of a current has occurred in the second dormant state in the same way.

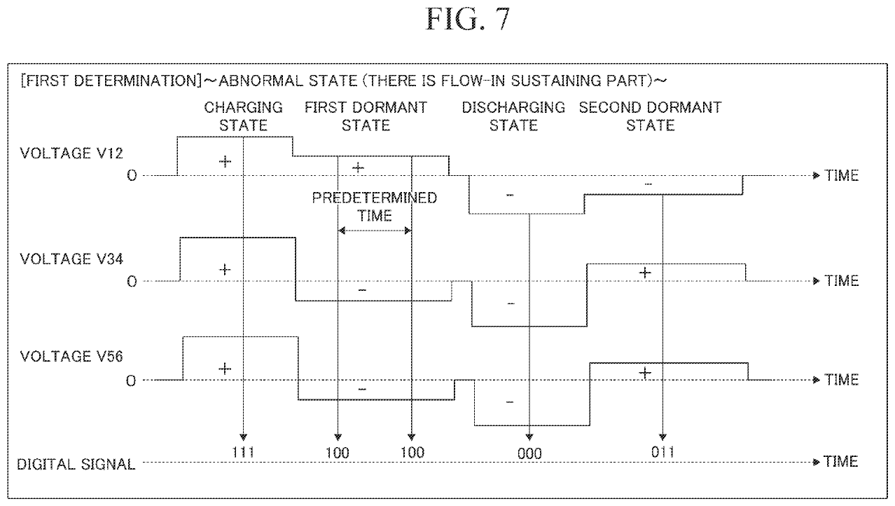

FIG. 7 is a timing chart illustrating an example of determination results of first determination. The voltage V12 in the drawing corresponds to V12 in FIG. 5 and indicates a voltage applied to the current direction sensing element 143A of the all-solid-state battery unit 100A. Similarly, the voltage V34 in the drawing corresponds to V34 in FIG. 5 and indicates a voltage applied to the current direction sensing element 143B of the all-solid-state battery unit 100B. Similarly, the voltage V56 corresponds to V56 in FIG. 5 and indicates a voltage applied to the current direction sensing element 143C of the all-solid-state battery unit 100C. Similarly to FIG. 6, FIG. 7 illustrates a transition example of a voltage value when the target unit transitions sequentially from a state in which the voltage is 0 to a charging state, a first dormant state after charging has stopped, a discharging state, and a second dormant state after discharging has stopped.

In this case, when the target unit is normal, the same transition will appear in both the voltage V12, the voltage V34, and the voltage V56. For example, similarly to the example in FIG. 6, the voltage in the charging state is positive, and the voltages in the first dormant state, the discharging state, and the second dormant state are equal to or lower than 0. That is, when the signs of the voltages are represented as digital signals (where a positive value is defined as 1 and zero or a negative value is defined as 0), the first determination unit 321 (or the second determination unit 322) can recognize the state transition in signal patterns of 111, 000, 000, and 000.

On the other hand, when a minute short circuit has occurred in the target unit, the voltage V12, the voltage V34, and the voltage V56 do not show the same transition patterns. For example, as in the example illustrated in FIG. 7, when the all-solid-state battery unit 100A is a flow-in sustaining part, a state different by the voltage V12 is observed in the dormant state. That is, when the signs of the voltages are represented as digital signals, the first determination unit 321 recognizes the states of the target unit in signal patterns of 111, 100, 000, and 011. For example, in this case, the first determination unit 321 can detect the signal patterns (100 and 011 herein) other than 111 and 000 as an abnormality. The first determination unit 321 (or the second determination unit 322) does not need to always monitor signal values for detecting an abnormality and can detect whether there is a flow-in sustaining part by determining voltage signs at a predetermined timing. The first determination unit 321 (or the second determination unit 322) may determine whether there is a flow-in sustaining part by combining a plurality of observed signal patterns similarly to the third determination unit 323.

As described above with reference to FIG. 4, the first determination unit 321 determines that there is a flow-in sustaining part when the signs of the voltages (currents) in the dormant state do not change in a predetermined period. FIG. 7 illustrates an example in which the first determination unit 321 determines that there is a flow-in sustaining part because the signs in the first dormant state do not change in a predetermined period. The signs at two time points are used to determine whether the signs change herein, but the signs at three or more time points may be used to determine whether the signs change. In this case, the first determination unit 321 can also determine whether there is a flow-in sustaining part in the second dormant state in the same way. The predetermined period in FIG. 6 and the predetermined period in FIG. 7 do not need to have the same time length, and may be individually set to appropriate time lengths according to detection purposes, preliminary test results, and the like.

With the aforementioned minute short circuit detection device 300 according to this embodiment, it is possible to detect whether a minute short circuit has occurred in a target unit by performing the first determination or/and the second determination on self-discharge in the dormant state of the all-solid-state battery unit 100 or the all-solid-state battery unit 200 which is a target unit.

More specifically, in an all-solid-state battery unit according to the related art, an input and an output in a basic unit are measured, what discharge is performed in the unit may not be ascertained, and it may not be possible to determine whether a minute short circuit has occurred. On the other hand, with the all-solid-state battery units 100 and 200 according to the embodiment do not include a liquid material, it is possible to more accurately ascertain discharging statuses in the unit and to accurately determine whether a minute short circuit has occurred by arranging the current direction sensing element for each electrode using characteristics of an all-solid-state battery that the degree of freedom in component arrangement is high (or the degree of difficulty is low) because a liquid material is not used. Since the minute short circuit detection device 300 according to the embodiment detects a minute short circuit using signs of currents or voltages in a target unit, measurement of currents or voltages in the target unit with high accuracy is not needed as long as the signs of the currents or the voltages in the target unit can be accurately recognized. That is, since the minute short circuit detection device 300 according to the embodiment does not require high-accuracy elements (for example, shunt resistors) as the current direction sensing element, it is possible to enable use of small elements at low costs. With the minute short circuit detection device 300 according to the embodiment, it is possible to enhance a degree of freedom in component arrangement in this regard. As long as the current direction sensing elements can be arranged, the target unit need not be an all-solid-state battery, but may be a battery using a liquid material.

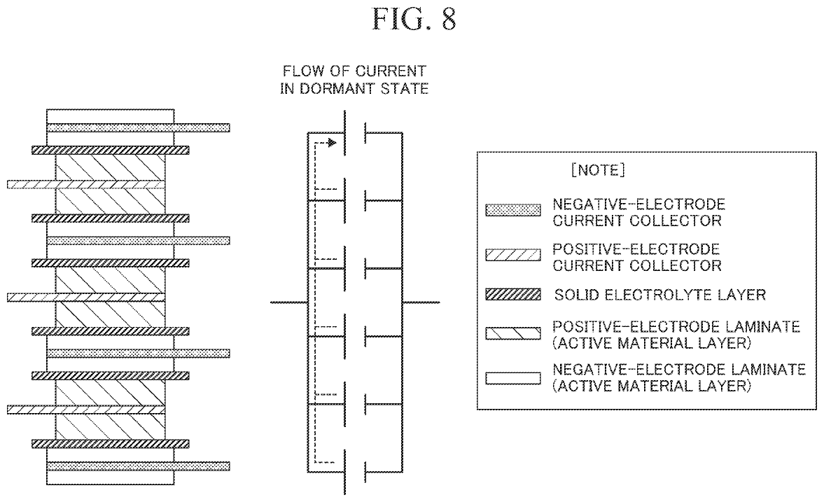

Since a stacked type all-solid-state battery unit according to the related art has a sheet-stacked structure in which a positive electrode and a negative electrode are simply stacked, for example, as illustrated in FIG. 8, it takes time to determine that a minute short circuit has occurred, and it takes long time to detect an abnormality. For example, in the sheet-stacked structure illustrated in FIG. 8, since six batteries are simply connected in parallel, an abnormality is averaged in the whole all-solid-state battery unit even when one of the six batteries is abnormal, and it is difficult to rapidly detect an abnormality. Accordingly, with the configuration according to the related art, an abnormality may be able to be detected at last only when an abnormality has occurred in a plurality of batteries. On the other hand, since the all-solid-state battery unit 200 according to the embodiment employs a configuration in which positive electrodes and negative electrodes are stacked in a plurality of bundles (see FIG. 2), it is possible to determine whether a minute short circuit has occurred for a shorter time by rapidly performing the first determination and the second determination.

While a mode for carrying out the present invention has been described above with reference to an embodiment, the present invention is not limited to the embodiment and can be subjected to various modifications and replacements without departing from the gist of the present invention.

What is claimed is:

1. A minute short circuit detection device that detects whether a minute short circuit has occurred in a battery unit including a positive electrode layer, an electrolyte layer, and a negative electrode layer, the minute short circuit detection device comprising:
a voltage detecting unit configured to detect a voltage of the battery unit;
a current detecting unit configured to detect a current flowing in the battery unit;
a storage device configured to store a program; and
a hardware processor,
wherein the hardware processor is configured to execute the program stored in the storage device to determine whether a minute short circuit has occurred in the battery unit on the basis of a detection result of the voltage or the current, and
wherein the hardware processor determines whether a minute short circuit has occurred on the basis of the detection result of the current and a sign of a voltage applied to the battery unit in a dormant state.

2. The minute short circuit detection device according to claim 1, wherein the battery unit includes a first negative-electrode current collector, a first negative-electrode active material layer, a first electrolyte layer, a first positive-electrode active material layer, a positive-electrode current collector, a second positive-electrode active material layer, a second electrolyte layer, a second negative-electrode active material layer, and a second negative-electrode current collector, and
wherein the current detecting unit is provided in at least the first negative-electrode current collector and the second negative-electrode current collector.

3. The minute short circuit detection device according to claim 2, wherein the current detecting unit is additionally provided in the positive-electrode current collector.

4. The minute short circuit detection device according to claim 1, wherein the battery unit includes a first positive-electrode current collector, a first positive-electrode active material layer, a first electrolyte layer, a first negative-electrode active material layer, a negative-electrode current collector, a second negative-electrode active material layer, a second electrolyte layer, a second positive-electrode active material layer, and a second positive-electrode current collector, and
wherein the current detecting unit is provided in at least the first positive-electrode current collector and the second positive-electrode current collector.

5. The minute short circuit detection device according to claim 4, wherein the current detecting unit is additionally provided in the negative-electrode current collector.

6. The minute short circuit detection device according to claim 1, wherein an electrolyte constituting the electrolyte layer is a solid electrolyte.

7. The minute short circuit detection device according to claim 1, wherein the battery unit includes one or more basic units in which two batteries are connected in parallel, and
wherein the hardware processor determines whether a current in each basic unit flows back on the basis of a sign of a voltage applied to the basic unit.

8. The minute short circuit detection device according to claim 1, wherein the battery unit includes a plurality of basic units in which two batteries are connected in parallel, and
wherein the hardware processor detects a basic unit into which a current continues to flow out of the plurality of basic units on the basis of a sign of a voltage applied to each basic unit.

9. The minute short circuit detection device according to claim 1, wherein the hardware processor determines whether a self-discharge rate of the battery unit is greater than a prescribed value on the basis of a voltage applied to the battery unit.

10. The minute short circuit detection device according to claim 1, wherein the hardware processor performs a motion of curbing charging of the battery unit when it is determined that a minute short circuit has occurred in the battery unit.

11. A minute short circuit detection method that is performed by a minute short circuit detection device that detects whether a minute short circuit has occurred in a battery unit including a positive electrode layer, an electrolyte layer, and a negative electrode layer, the minute short circuit detection method causing the minute short circuit detection device to perform:
detecting a voltage of the battery unit;
detecting a current flowing in the battery unit; and
determining whether a minute short circuit has occurred in the battery unit on the basis of a detection result of the voltage or the current,
wherein the minute short circuit detection device determines whether the minute short circuit has occurred on the basis of the detection result of the current and a sign of a voltage applied to the battery unit in a dormant state.

12. A non-transitory computer-readable storage medium storing a program that is executed by a minute short circuit detection device that detects whether a minute short circuit has occurred in a battery unit including a positive electrode layer, an electrolyte layer, and a negative electrode layer, the program causing the minute short circuit detection device to perform:
detecting a voltage of the battery unit;
detecting a current flowing in the battery unit; and
determining whether a minute short circuit has occurred in the battery unit on the basis of a detection result of the voltage or the current,
wherein the minute short circuit detection device determines whether a minute short circuit has occurred on the basis of the detection result of the current and a sign of a voltage applied to the battery unit in a dormant state.

13. A battery unit in which a first negative-electrode current collector, a first negative-electrode active material layer, a first electrolyte layer, a first positive-electrode active material layer, a positive-electrode current collector, a second positive-electrode active material layer, a second electrolyte layer, a second negative-electrode active material layer, and a second negative-electrode current collector are sequentially stacked,
wherein a current detecting unit is provided in at least the first negative-electrode current collector and the second negative-electrode current collector.

14. A battery unit in which a first positive-electrode current collector, a first positive-electrode active material layer, a first electrolyte layer, a first negative-electrode active material layer, a negative-electrode current collector, a second negative-electrode active material layer, a second electrolyte layer, a second positive-electrode active material layer, and a second positive-electrode current collector are sequentially stacked, and
wherein a current detecting unit is provided in at least the first positive-electrode current collector and the second positive-electrode current collector.
